(19) United States
(12) Patent Application Publication
(10) Pub. No.: US 2018/0146276 A1
(43) Pub. Date: May 24, 2018

(54) STARTUP CIRCUIT AND METHODS OF USE FOR AUDIO ACCESSORIES

(71) Applicant: QUALCOMM Incorporated, San Diego, CA (US)

(72) Inventors: Meysam Azin, San Diego, CA (US); Hui-ya Liao Nelson, San Diego, CA (US); Mark Cherry, Oceanside, CA (US); Jingxue Lu, San Diego, CA (US)

(21) Appl. No.: 15/472,017

(22) Filed: Mar. 28, 2017

Related U.S. Application Data
(60) Provisional application No. 62/425,404, filed on Nov. 22, 2016.
(60) Provisional application No. 62/450,139, filed on Jan. 25, 2017.

(51) Int. Cl. H04R 1/10; G06F 3/16; H03H 7/32

(52) U.S. Cl. CPC H04R 1/1041; H03H 7/32; G06F 3/165

(57) ABSTRACT

An accessory device, configured to be interfaced with a master device, and configured to operate in an analog mode and in a digital mode, the accessory device including: a startup circuit including: a first transistor that interfaces the accessory device to the master device, wherein the first transistor is configured with a first resistive capacitive (RC) circuit to turn on the first transistor according to a time constant of the first RC circuit; a second transistor coupled between ground and the first RC circuit, wherein the second transistor is configured to control a gate of the first transistor in response to a control signal; and a diode having an anode coupled to the first node and a cathode coupled to a body terminal of the first transistor.

### CROSS-REFERENCE TO RELATED APPLICATIONS

The present application claims the benefit of U.S. Provisional Patent Application No. 62/425,404, filed Nov. 22, 2016, and entitled “STARTUP CIRCUIT AND METHODS OF USE FOR AUDIO ACCESSORIES,” and claims the benefit of U.S. Provisional Application 62/450,139, filed Jan. 25, 2017, and entitled “STARTUP CIRCUIT AND METHODS OF USE FOR AUDIO ACCESSORIES”, the disclosures of which are incorporated by reference herein in their entirety.

### TECHNICAL FIELD

This application relates to startup circuits, and more particularly, to startup circuits for use in audio accessory devices.

### BACKGROUND

An example conventional system may include a master device, such as a smart phone or tablet, which is coupled with an accessory device, such as a headset or earbud set. The master device and accessory device are coupled by a jack and plug connection, such as a standard 3.5 mm audio jack. During normal operation, the master device outputs analog audio signals to the headset or earbud set, and the headset or earbud set includes transducers, such as speakers, to generate sound waves. The headset or earbud set may also include a microphone that generates analog electrical signals for transmission back to the master device.

Such system may further include a pause/play button on the accessory device, allowing a user to send a signal to the master device to control audio output. For instance, the user may physically depress a button on the accessory device, thereby causing a microphone line of the accessory device to terminate at ground through one or more known impedances. The value of the termination impedance determines the meaning of the signal. For instance, the signal may include volume up, volume down, play/pause, and the like. The master device detects termination of the microphone line, determines the termination impedance, and acts according to the determination. For instance, the master device may be programmed to associate a particular impedance with volume up, another impedance of volume down, and the like. In response to determining a particular termination impedance, the master device may undertake an appropriate action, such as adjusting the volume or pausing audio.

It would be desirable to include digital communication capabilities in an accessory device, and it would also be desirable that the accessory device would be backward-compatible with master devices that may not support digital communication through an audio jack. It would also be desirable for the accessory device to limit rush current and to maintain high quality of audio signals.

### SUMMARY

According to one embodiment, an accessory device, configured to be interfaced with a master device, and configured to operate in an analog mode and in a digital mode, the accessory device including: a startup circuit including: a first transistor that interfaces the accessory device to the master device, wherein the first transistor is configured with a first resistive capacitive (RC) circuit to turn on the first transistor according to a time constant of the first RC circuit; a second transistor coupled between ground and the first RC circuit, wherein the second transistor is configured to control a gate of the first transistor in response to a control signal; a comparator in communication with the second transistor and coupled with a first node interfacing the master device to the accessory device, the comparator configured to provide the control signal in response to a voltage rise at the first node; and a diode having an anode coupled to the first node and a cathode coupled to a body terminal of the first transistor.

According to another embodiment, a method performed by an audio accessory device, the method including: operating the audio accessory device in a first mode, wherein the audio accessory device comprises a first node interfacing the audio accessory device to a master device, the audio accessory device further comprising a first transistor coupled between the first node and a processor chip of the audio accessory device and coupled between the first node and a capacitor, wherein a diode is coupled between the first node and the capacitor and is coupled with a body terminal of the first transistor, wherein during the first mode current is supplied from the master device to the processor chip through a first resistor coupled between the first node and the processor chip; changing from the first mode to a second mode, including charging the capacitor through the diode and pulling down a gate of the first transistor in accordance with a time constant of a first resistive capacitive (RC) circuit coupled to the gate of the first transistor; and operating the audio accessory device in the second mode, including supplying current from the master device to the processor chip through the first transistor.

According to another embodiment, an audio accessory device including: a first node interfacing with a master device, the first node configured to receive power from the master device and to transmit digital signals between the master device and audio accessory device; means for conducting current from the first node to a processor chip of the audio accessory device, wherein the means for conducting current includes a first transistor and a diode having its cathode coupled with a body terminal of the first transistor, wherein the diode is configured to conduct current from the first node to the processor chip; and means for turning on the first transistor according to a first RC time constant.

### BRIEF DESCRIPTION OF THE DRAWINGS

FIG. 1 illustrates an example master and slave system, providing for digital communication between an accessory device and a master device, in accordance with an embodiment of the disclosure.

FIG. 2 illustrates an example master and slave system in accordance with one embodiment of the disclosure.

FIG. 3 illustrates an example master and slave system in accordance with an embodiment of the disclosure.

FIG. 4 illustrates an example simplified circuit diagram of the system of FIG. 3 in an analog operating mode, according to one embodiment of the disclosure.

FIG. 5 illustrates an example simplified circuit diagram of the system of FIG. 3 in a digital operating mode, according to one embodiment of the disclosure.

FIG. 6 is an illustration of an example method to be performed with the systems of FIGS. 1-5, according to an embodiment of the disclosure.

### DESCRIPTION

Circuits and methods providing both analog and digital operating modes in an accessory device are provided herein. For instance, an accessory device may include a startup circuit having soft start capabilities. During a transition from the analog operating mode to the digital operating mode, the startup circuit having soft start capabilities may reduce an amount of rush current to acceptable levels. Furthermore, the example system may include appropriate impedance to maintain low total harmonic distortion (THD) and high signal-to-noise ratio (SNR) for analog signals.

In one example an accessory device may be configured to be interfaced with a master device by a jack and plug connection, such as a 3.5 mm audio jack. The accessory device may be also configured to operate in an analog mode and in a digital mode. The accessory device may include a startup circuit that has a first transistor, and the first transistor interfaces the accessory device to the master device. The first transistor has a resistive capacitive (RC) circuit coupled with its gate and either its drain or its source. The RC circuit has an associated RC time constant, and the rate at which the first transistor turns on may be determined, at least in part, by the RC time constant.

The accessory device also may include a second transistor that may be coupled between ground and the first RC circuit. When the second transistor is turned on, it pulls down a voltage at the gate of the first transistor, which turns the second transistor on. However, the first transistor may not turn on instantaneously, as explained above. Rather, the first transistor may turn on gradually according to the time constant of the RC circuit.

The second transistor may be turned on using a control signal that is generated by, e.g., a comparator. In a system in which analog mode includes a first voltage level and in which the digital mode includes a second, higher voltage level, the comparator may receive a reference voltage at the first voltage level so that it outputs a logic level 1 (high) for the control signal when a line voltage level exceeds the first voltage level. This may allow the comparator to detect whether the accessory device is operating in the analog mode or the digital mode.

The startup circuit also may include an additional RC circuit at a node that interfaces the master device to the accessory device. The additional RC circuit may be coupled to an input of the comparator, thereby adding a time delay between the voltage rise at the first node and a change in state of the control signal. The resistor and capacitor of the additional RC circuit may be chosen to have values that provide a time delay of appropriate length. For instance, in some applications a delay as short as is practical may be desirable, and therefore, the delay of the second RC circuit may be designed to be 1 ms or less.

Returning to the first transistor, the first transistor may include a diode having its anode coupled with the node that interfaces with the master device. The cathode may be coupled to a body terminal of the first transistor and to either the source or drain of the first transistor through a first resistor. The diode conducts current from the master device to a capacitor during a transition from the analog mode to the digital mode. However, once the startup circuit is in steady-state in the digital mode, the first transistor is turned on, and current bypasses the diode through the first transistor and is supplied to a processing circuit of the accessory device. During steady-state of the analog mode, current bypasses the diode and the first transistor and instead may be conducted to the processing circuit of the accessory device by a second resistor. The second resistor may be chosen to have a value that reduces or minimizes attenuation of microphone signals during the analog mode, thereby providing relatively high SNR and relatively low THD.

The diode and the first resistor may be selected so that current to charge the capacitor does not exceed an appropriate level during transition from the analog mode to the digital mode. For instance, the value of the first resistor may be chosen so that current through the diode may be no larger than 50 mA. Of course, the scope of embodiments is not limited to any particular RC constant, any particular voltage, or any particular current value. Rather, various embodiments may be adapted for use as appropriate.

Other embodiments include methods of use of the circuits described herein. For instance, one method may include operating the accessory device in a first analog mode, changing from the first analog mode to a second digital mode, and then operating the accessory device in the second digital mode.

Various embodiments provide one or more advantages. For instance, some embodiments allow for transition from an analog mode to digital mode with controlled rush current. As noted above, the diode and first resistor may be sized appropriately to limit rush current. Similarly, the time delay of the first RC circuit associated with the gate of the first transistor may be chosen to limit rush current during turn on of the first transistor. Also, the comparator may be triggered to switch a state of the control signal after an acceptable time delay, as noted above. Additionally, the use of a resistor of appropriate size to provide leakage current to the processing circuit during analog mode may provide acceptable levels of THD and SNR for a given application.

Various embodiments may be backward-compatible with master devices that do not offer a digital communication mode through the audio jack because the digital mode circuitry (and including the startup circuitry) may remain turned off as long as the line voltage stays within a level associated with the analog mode.

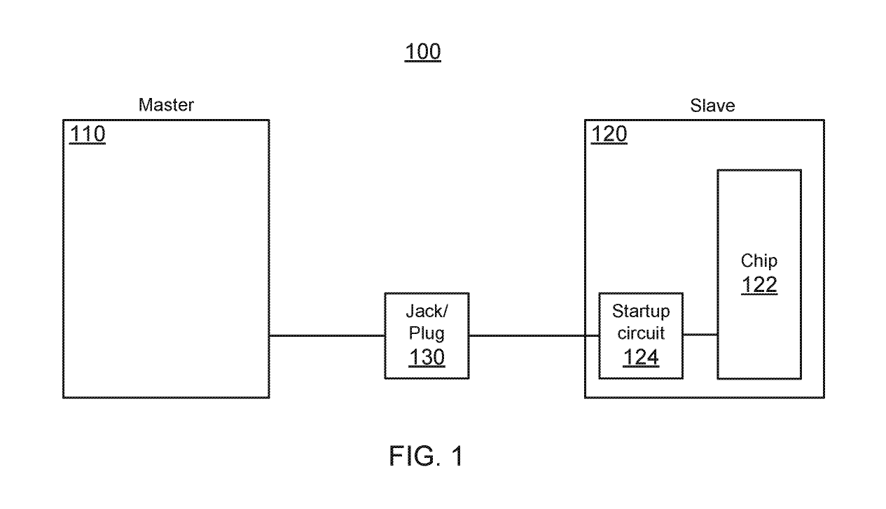

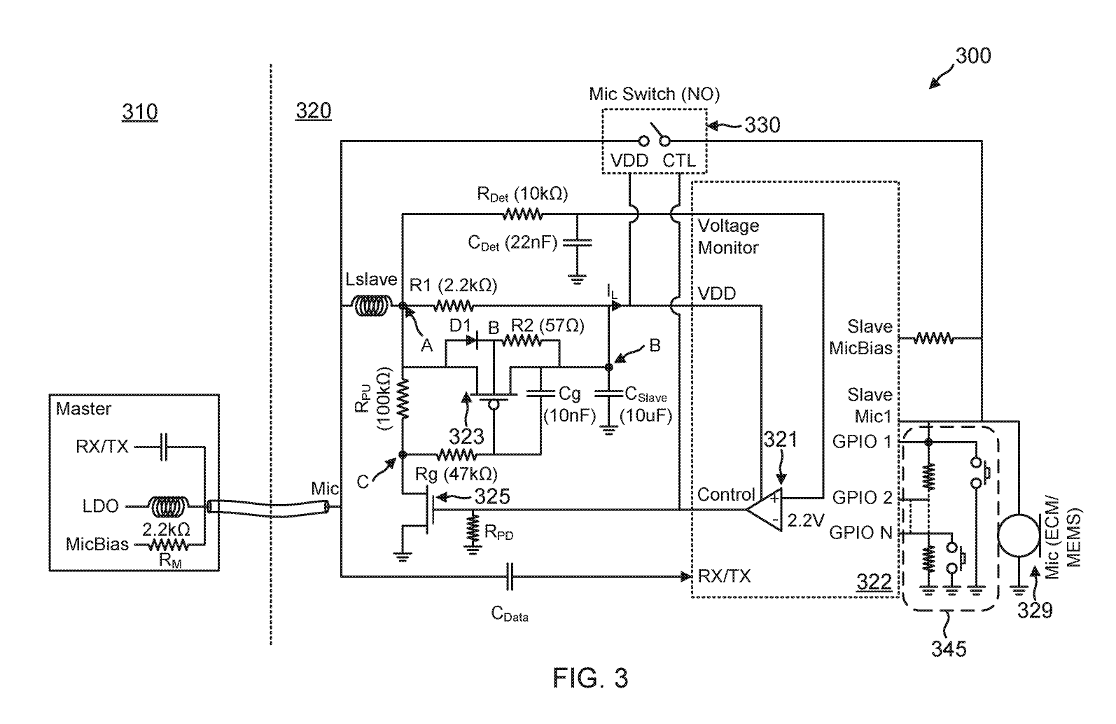

FIG. 1 illustrates an example master and slave system, according to one embodiment. The example of FIG. 1 may include a master device 110, such as a smart phone or tablet computer, and the slave device 120 may include a headset or other audio accessory device. The master device 110 and the slave device 120 may be electrically communicatively coupled by a jack and plug 130, such as a 3.5 mm audio connection. The slave device 120 may include a processing circuit 122, such as a processor chip. The processing circuit 122 interfaces with the audio connection by a startup circuit 124. An example startup circuit 124 is described in more detail below with respect to FIG. 3.

The scope of embodiments is not limited to any particular master device. In addition to smart phones and tablet computers, other devices that may be used as master devices include laptop computers with audio jacks, car stereos with audio jacks, and the like. Furthermore, accessory devices may include headsets and earbuds as well as gaming audio-video devices, biosensors, noise canceling devices, and the like.

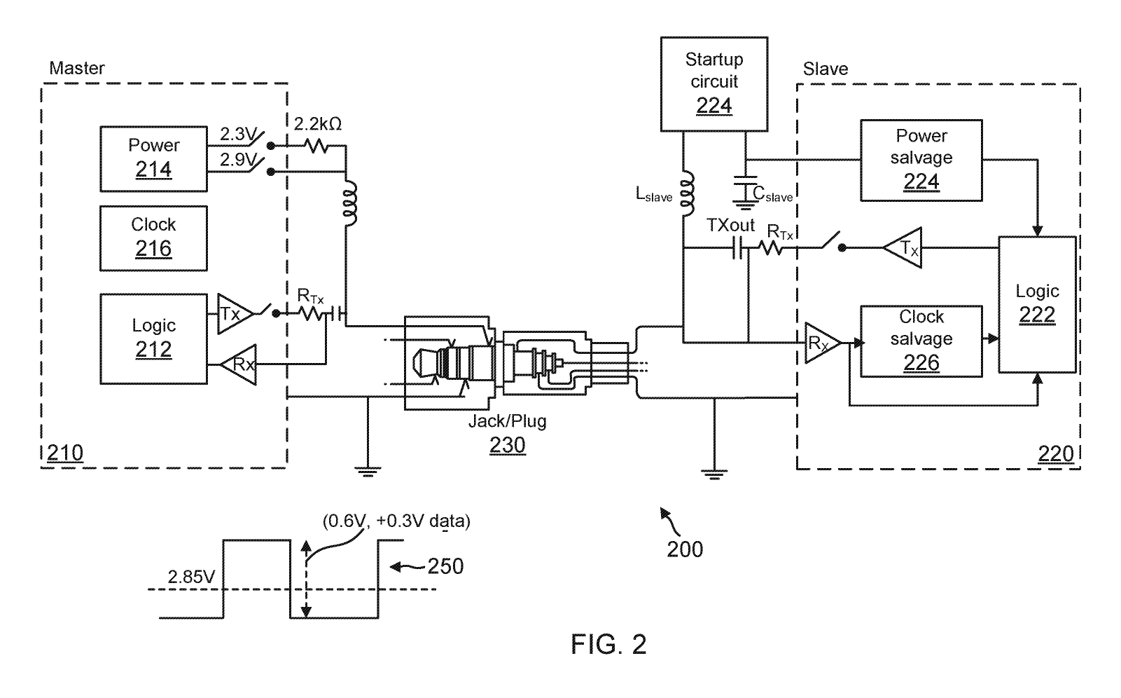

FIG. 2 is an illustration of another example master slave system 200, adapted according to one embodiment. The illustration of FIG. 2 is offered to provide more detail regarding an implementation of the simplified diagram of FIG. 1. For instance, master device 210 provides an example implementation for master device 110, slave device 220 provides an example implementation for slave device 120, and startup circuit 224 illustrates an example placement of a startup circuit within system 200.

As with FIG. 1, master device 210 may include any appropriate device, such as a smart phone, tablet computer, laptop, or the like. Similarly, the slave device 220 may include an audio accessory device, such as a set of earbuds or an audio headset. Jack and plug connector 130 is shown as a 3.5 mm audio jack in this example embodiment.

Further this example embodiment, the jack and plug connector 230 may include four conductors: left speaker, right speaker, microphone, and ground. In this example embodiment, left speaker and right speaker may be used for analog audio signals during the analog mode of operation, and the microphone conductor has dual uses. For instance, FIG. 2 illustrates that the microphone conductor may be used for transmission of analog audio signals from the microphone at slave 220 to the master device 210 during the analog mode of operation. Furthermore, the embodiment of FIG. 2 uses the microphone conductor for power, clock, and digital signals during the digital mode of operation. FIG. 2 illustrates the path for signals and data in the digital operating mode and omits the analog audio path for ease of illustration. Nevertheless, it is understood that various embodiments may include analog audio path circuitry in addition to digital mode circuitry.

Master device 210 may include a power module 214, which has two operating modes, a 2.3 V operating mode, and a 2.9 V operating mode. The 2.3 V operating mode may be associated with the analog operating mode, whereas the 2.9 V operating mode may be associated with the digital operating mode. As discussed further below, the slave device 220 may determine whether it is desired to operate in the analog mode or the digital mode based, at least in part, on the line voltage from the jack and plug connector 230. In other words, the 2.3 V line voltage may be seen at the slave device 220 as approximately 2.2 V; accordingly, the slave device 220 assumes the digital operating mode when it detects a line voltage above about 2.2 V. Such feature may allow slave device 220 to be backward-compatible with other master devices that do not support a digital mode of operation. Specifically, when used with a legacy master device, slave device 220 may see a line voltage no higher than about 2.2 V and may accordingly assume the analog operating mode.

Logic circuit 212 may include any appropriate processing device, such as a chip in an audio card, a DSP in a larger system on chip (SOC), and/or the like. In short, in the digital operating mode, logic circuit 212 exchanges digital signals with logic circuit 222 over the jack and plug connector 230. Further in this example, the slave device 220 does not have a power supply of its own, nor a clock of its own, and it receives the power and clock from the master device 210 over jack and plug connector 230. As shown in the signal diagram 250, the digital operating mode may include a 2.85 V DC bias, with the digital data being applied as plus or minus 0.3 V on top of the DC bias.

Continuing with the example, slave device 220 may include clock salvage circuit 226 to recover the clock signal and to pass the clock signal to the logic circuit 222. The capacitor labeled TXout shields the transmission path and the logic circuit 222 from the 2.85V DC bias.

The path for power may include the inductor labeled Lslave, the startup circuit 224, the capacitor labeled Cslave, and the power salvage circuit 224. Lslave and Cslave may be used as an LC filter to remove digital data, allowing power salvage circuit 224 to provide clean DC power to logic circuit 222. As explained in more detail below, startup circuit 224 may reduce or minimizes rush current when the slave device 220 switches between an analog operating mode in a digital operating mode, and it may also provide a relatively quick switching operation between modes.

The embodiment of FIG. 2 includes values for resistances and voltages, and it is understood that these values are for example only. Other embodiments may be adapted for use with different resistances and voltage values. Also, other embodiments may be adapted for use with different types of connections between the master device 210 and slave device 220, the scope of embodiments is not limited to a 3.5 mm audio jack.

FIG. 3 is an illustration of example master and slave system 300, adapted according to one embodiment. FIG. 3 is offered to show a master and slave architecture according to the general architecture of FIG. 1 and according to the architecture of FIG. 2. Put another way, master and slave system 300 of FIG. 3 illustrates an implementation of the principles discussed above with respect to FIGS. 1 and 2. Similar to FIG. 2, the embodiment of FIG. 3 omits analog mode audio paths for ease of illustration. Furthermore, the embodiment of FIG. 3 also assumes a 2.2 V analog operating mode and a 2.85 V digital operating mode at the audio accessory side. FIG. 3 also omits illustration of a jack and plug connector, and it is understood that a connector, such as a jack and plug connector 230, may be implemented between the master device 310 and the slave device 320. The startup circuit 124 of FIGS. 1 and 224 of FIG. 2 is represented in FIG. 3 as the system including an RC circuit (R_{DET} and C_{DET}), the comparator 321, the NMOS transistor 325, another RC circuit (R_{g} and C_{g}), a PMOS transistor 323, diode D1, and resistor R2.

At the master device 310, the view is simplified to include digital signal path RX/TX, a low drop out voltage source (LDO), and an analog microphone bias input (MicBias) having a series resistor R_{M}. During an analog operating mode, MicBias provides about 2.2 V as seen at the accessory device 320. However, during a digital mode of operation, the LDO provides the 2.85 V line voltage seen at the accessory device 320. A user of an advanced audio accessory (e.g., device 320) that supports digital communication may use the accessory in either the analog mode or the digital mode, depending upon a given application being used or media being consumed. The switch between analog and digital mode in an advanced accessory device may present the possibility of rush current and unnecessary delay between operational modes.

Circuits and techniques are proposed to handle digital mode to analog mode transition in advanced audio accessories with minimum impact on analog mode audio quality as measured by THD and SNR. Various embodiments may include advanced audio accessories having a startup circuit providing for a soft start and short delay when switching between analog and digital modes of operation. An example is illustrated in FIG. 3.

In the analog mode the microphone may be biased through R_{M} (in this example, 2200 ohms) and therefore the voltage at node A may be less than 2.0 V, and the comparator 321 outputs the control signal as low (e.g., 0 V). This turns the switch 330 on, and the p-channel MOSFET (PMOS) transistor 323 and the n-channel MOSFET (NMOS) transistor 325 are off. Thus, the microphone 329 may be coupled to the master device 310 via the switch 330.

During steady state of the analog mode, leakage current may be provided to the logic circuit 322 by resistor R1. In this example, R1 may be equal to 2200 ohms, which may be enough to provide leakage current to the logic circuit 322 while providing low attenuation to the microphone 329. Other embodiments may use different values for R1, such as 4700 ohms. Note that the resistor R_{M} at the master side may be 2200 ohms thus leading to low attenuation for the signal between the master device 310 and the microphone 329. Also, the capacitor Cslave is fully charged, so the diode D1 is turned off. Circuit 345 may include pressable switches connecting known impedance values to ground to provide GPIO signals (e.g., volume up or down, pause, etc.) to logic circuit 322.

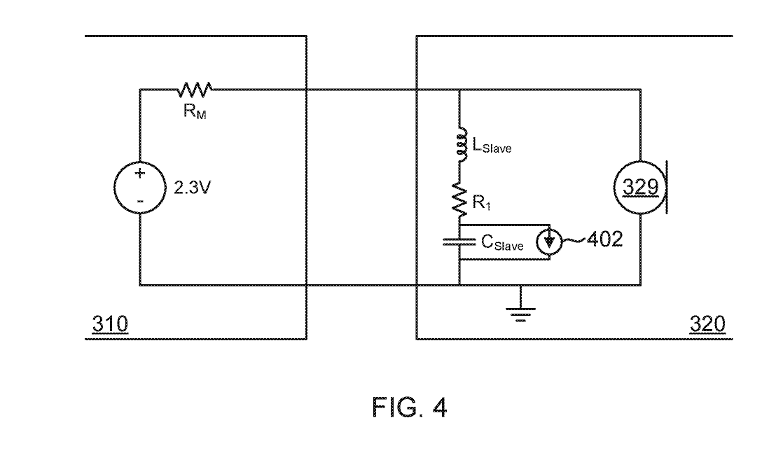

FIG. 4 is a simplified diagram providing an illustration of the system 300 of FIG. 3 during steady-state of the analog operating mode, according to one embodiment. At the slave device 320, the resistor R1 may be on a current path that is parallel to the current path including resistor R_{M}. Assuming that both R_{M} and R1 have a value of 2200 ohms, then the ratio of current reaching the master device from the microphone 329 may be approximately one-half. In other words, the ratio of current reaching the master device 310 from the microphone 329 may be roughly equal to R1/(R_{M}+R1) or 2200/(2200+2200). Thus, the present embodiment selects a value for R1 that provides relatively low attenuation for microphone signals and, thus, low THD and high SNR. Of course, the values for R1 and R_{M} are for example only, and other embodiments may be adapted appropriately. In a different embodiment in which the value of R1 may be 4700 ohms, attenuation may be even lower than in the example above. Current source 402 is shown in parallel with Cslave to model small current slave device draw for comparator operation and leakage of miscellaneous blocks (not shown).

Returning to FIG. 3, now the example transitions to a scenario where the system changes from an analog operating mode to the digital operating mode. The MicBias turns off at the master device 310, and the LDO at the master device 310 turns on. Since the voltage is initially below 2.0V, the control signal is low, so the NMOS 325 and PMOS 323 transistors are turned off. Once the voltage between node A and node B rises above about approximately 0.5 V, this forward biases diode D1, and diode D1 begins to conduct current to charge capacitor Cslave. If node A is considered an input and node B is considered an output, then diode D1 may be arranged to conduct current from input to output during this period of the operating mode. Also, the body of the PMOS transistor 323 may be coupled to the output by resistor R2 and may be coupled to the cathode of diode D1. The anode of diode D1 may be coupled to either the source or drain of PMOS transistor 323, and resistor R2 may be coupled to the other of the source or drain of PMOS transistor 323, thereby creating a current path around transistor 323. As the voltage rises, diode D1 stays on until Cslave may be charged to the line voltage.

The value of R2 may be chosen to limit rush current. For instance, in one example, (V_{DIG}-V_{DON})/R2 may be less than 50 mA, wherein V_{DIG} is an operating voltage of the digital mode, and wherein V_{DON} is a voltage difference at which the diode D1 turns on. In this example, V_{DIG} may be about 2.85 V and V_{DON} may be about 0.5 V, and values for resistance and capacitance shown in FIG. 3 result in the rush current being less than 50 mA, though the scope of embodiments may include different values for resistance and capacitance as appropriate. Also, the value of R1 may be chosen to be large enough to prevent diode D1 from turning on in the analog mode (i.e., R1<V_{DON}/I_{L}), while providing adequate leakage current to the processing circuit 322 during the analog operating mode, in some instances.

The comparator 321 receives a reference input of 2.2 V at its inverting input. During the transition from analog mode to digital mode, the voltage at node A passes 2.2 V, and the non-inverting input at the comparator 321 sees that voltage after a delay due to the RC circuit made up of R_{DET} and C_{DET}. The resistance of R_{DET} and the capacitance of C_{DET} may be set to a low RC constant and a small delay of about 1 ms. In this example, the RC circuit including R_{DET} and C_{DET} may be chosen to have a time constant low enough to cause a delay that is relatively short. However, the design of the circuit of FIG. 3 benefits from the presence of R_{DET}, so various embodiments use a value for R_{DET} that is non-zero. Of course, the particular values for R_{DET}, C_{DET}, and the delay attributable thereto are for example only, and other embodiments may use different values.

After the delay attributable to R_{DET} and C_{DET}, the control signal goes high, which turns off switch 330 and turns on the NMOS transistor 325. Once the NMOS transistor 325 turns on, this brings the voltage at node C low. The architecture of FIG. 3 includes an additional RC circuit having C_{g} and R_{g}. This additional RC circuit may be coupled to the gate electrode of the PMOS transistor 323. In one example, this additional RC circuit may be coupled between the drain of PMOS transistor 323 and the source of NMOS transistor 325.

The resistor R_{g} and capacitor C_{g} provide a gradual pull down of the gate of the PMOS transistor 323. Thus, instead of turning on as soon as the NMOS transistor 325 turns on, the RC circuit including R_{g} and C_{g} provides a gradual turn on and feedback that limits the amount of current conducted from node A to node B through the PMOS transistor 323. Another way to view the circuit of FIG. 3 is that there is a loop including node A, R_{DET} and C_{DET}, comparator 321, and the NMOS transistor 325 to control the RC circuit having R_{g} and C_{g} to provide the soft start by gradually pulling down the PMOS gate. Such feature may be meant to reduce or eliminate rush current at the transition from analog mode to digital mode. Once again, some example embodiments may include a goal to keep rush current at or below about 50 mA, and the rush current attributable to capacitor Cslave may be approximately Cslave*ΔV/Δt, where At is an elapsed time during the rise of the voltage. In the example of FIG. 3, the values shown for C_{g} and R_{g} may be chosen to limit rush current to no more than 50 mA. However, the scope of embodiments may include different values for C_{g} and R_{g} as appropriate.

Continuing with the example, the voltage at node A continues to rise from 2.2 V to 2.85 V. As the system continues to operate in a steady-state digital mode, any current provided to the processing circuit 322 may be provided through the PMOS transistor 323 because resistor R1 is bypassed, and diode D1 is turned off. When the voltage at node A exceeds 2.2V, the current to processing circuit 322 may be significant and may no longer be considered leakage current. During steady-state of the digital mode, the current provided through PMOS transistor 323 powers the processing circuit 322, and digital communication may be accomplished between the master device 310 and the slave device 320.

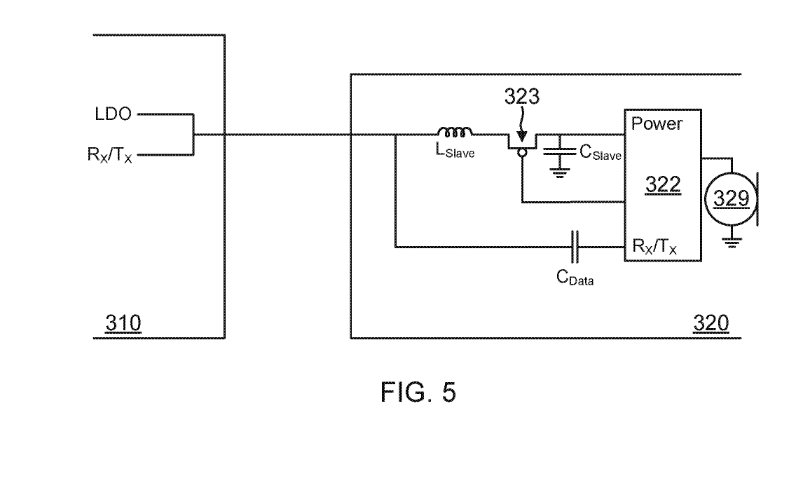

FIG. 5 is a simplified diagram providing an illustration of the system 300 of FIG. 3 during steady-state of the digital operating mode, according to one embodiment. The capacitor Cdata isolates the receive and transmit circuits for digital signals from the DC bias of the line voltage. Furthermore, the digital signals, the voltage from the LDO, and the clock may be provided to slave device 320 over the audio connection. The connection may be bidirectional, as the logic circuit 322 communicates to the master device 310 over the same connection. The microphone 329 may be powered by the logic circuit 322.

The system above provides several features that may be advantageous in some applications. First, the RC circuit including R_{DET} and C_{DET} has a relatively low RC time delay, providing for a relatively quick transition from analog mode to digital mode. This may increase enjoyability by a user, making the delay imperceptible or nearly imperceptible. Furthermore, the value of the resistor R1 may be large enough not to significantly impact the microphone signal and provide high SNR and THD in analog mode. This may also increase user experience by providing high quality audio. Furthermore, the RC circuit including C_{g} and R_{g} provides for a soft turn on of the PMOS transistor, which limits rush current during the transition from analog mode to digital mode. This may extend life of the device and reduce or eliminate annoying pops when transitioning to digital mode.

While the various embodiments have been described herein with respect to a 3.5 mm accessory jack, the scope of embodiments is not so limited. Rather, various embodiments may be applied to systems using legacy analog connections to provide an ability to switch between the legacy analog mode and an additional digital mode. Furthermore, while the examples herein have been described with respect to a headset, other accessories are within the scope of embodiments, such as audio systems having a line-in, fitness monitors, and the like that may act as audio accessories to interface with a legacy analog input. Additionally, since the accessory devices are configured to operate in an analog mode, they can be backward-compatible with older master devices.

It should also be noted that the particular values voltage, resistance, and capacitance in the above-described embodiments is for example, and scope of embodiments is not limited to those values. Rather, the various embodiments may be adapted for use as appropriate. Various embodiments also may include methods of use of the systems described above. Furthermore, other embodiments may use different transistor technologies (e.g., bipolar junction transistors) rather than metal oxide semiconductor (MOS) transistors. And while the example of FIG. 3 has PMOS transistor 323 and NMOS transistor 325 arranged as shown, other embodiments may switch the types of transistors.

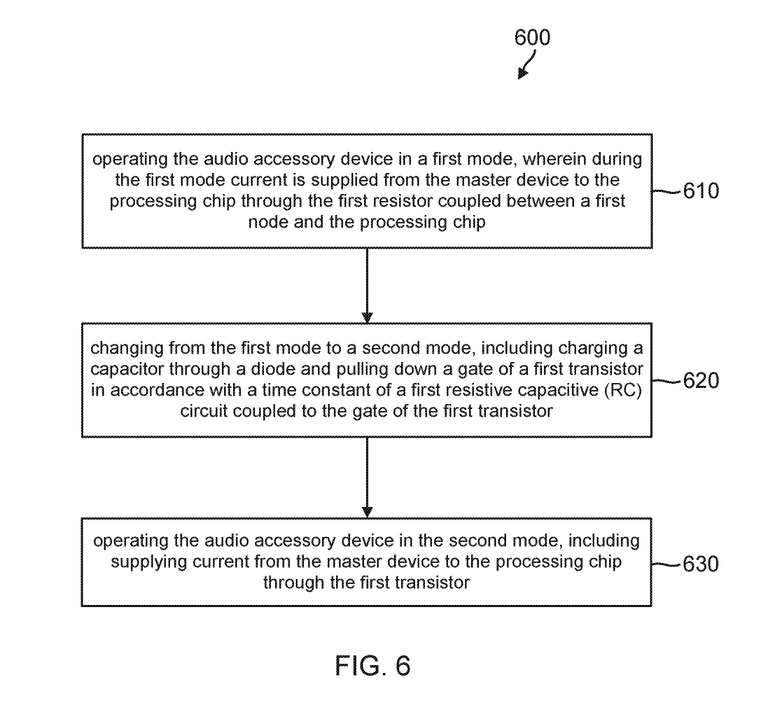

FIG. 6 is an illustration of an example method 600 in which the master and slave architectures shown in FIGS. 1-3 may be used. For instance, the actions 610-630 of method 600 may be performed by a slave device 120, 220, 320 of FIGS. 1-3. In some examples, the slave devices may include advanced audio accessory devices connected by a jack and plug connector to a master device. Examples of master and slave devices are given above with respect to the embodiments of FIGS. 1-3.

At action 610, the audio accessory device operates in a first mode. An example of the first mode includes an analog mode, such as illustrated above with respect to FIG. 4, and including transmission of analog signals. During the first mode, current may be supplied from the master device to a processing circuit of the slave device through a first resistor coupled between a first node and the processing circuit. An example of the processing circuit includes a processor chip (e.g., an SOC) or other semiconductor chip-based device. An example of the first node includes node A of FIG. 3, which interfaces device 320 to device 310. In the example of FIG. 3, during the analog mode, leakage current may be provided from the master device 310 to the processing circuit 322 via resistor R1. Also this example, the analog mode (e.g., the first mode) may be associated with a first voltage, and the digital mode (e.g., the second mode) may be associated with a second voltage, wherein the second voltage may be higher than the first voltage.

At action 620, the accessory device changes from the first mode to a second mode. Action 620 includes charging a capacitor through the diode and also pulling down a gate of the first transistor in accordance with the time constant of a first RC circuit coupled to the gate of the first transistor.

An example of action 620 is illustrated above at FIG. 3. During the transition from the first mode to the second mode, the diode D1 turns on and charges capacitor Cslave through resistor R2. D1 and R2 have characteristics selected to keep rush current below an established threshold (e.g., 50 mA). Once the capacitor is charged, the diode turns off.

In the example of FIG. 3, the transition from the first mode to the second mode also includes turning on the PMOS transistor 323. The process for turning on the PMOS transistor 323 may include a delay according to an RC time constant of R_{DET} and C_{DET}, a change in state of the control signal, turn on of the NMOS transistor 325, and gradual turn on of the PMOS transistor 323 according to a time delay associated with the other RC circuit having R_{g} and C_{g}. The comparator 321 outputs a high-voltage level for the control signal in response to sensing a particular voltage, such as a voltage that is higher than its reference voltage. The PMOS transistor 323 may be turned on by pulling down its gate, or put another way, reducing a voltage at its gate to a low voltage such as ground or nearly ground. Rush current may be reduced or minimized by virtue of D1 and R2 during a first portion of the mode transition and by the gradual turn on of the PMOS transistor 323 during a second portion of the mode transition.

At action 630, the accessory device operates in a second mode in which current may be supplied from the master device to the processing circuit through a transistor. An example is shown in FIGS. 3 and 5, in which the processing circuit 322 receives current during steady-state digital mode through the PMOS transistor 323. The second mode, e.g., digital mode, may further include exchange of digital data between the processing circuit at the master device and a processing circuit at the audio accessory device through the first node.

As those of some skill in this art will by now appreciate and depending on the particular application at hand, many modifications, substitutions and variations can be made in and to the materials, apparatus, configurations and methods of use of the devices of the present disclosure without departing from the spirit and scope thereof. In light of this, the scope of the present disclosure should not be limited to that of the particular embodiments illustrated and described herein, as they are merely by way of some examples thereof, but rather, should be fully commensurate with that of the claims appended hereafter and their functional equivalents.

What is claimed is:

1. An accessory device, configured to be interfaced with a master device, and configured to operate in an analog mode and in a digital mode, the accessory device comprising:
a startup circuit including:
a first transistor that interfaces the accessory device to the master device, wherein the first transistor is configured with a first resistive capacitive (RC) circuit to turn on the first transistor according to a time constant of the first RC circuit;
a second transistor coupled between ground and the first RC circuit, wherein the second transistor is configured to control a gate of the first transistor in response to a control signal;
a comparator in communication with the second transistor and coupled with a first node interfacing the master device to the accessory device, the comparator configured to provide the control signal in response to a voltage rise at the first node; and
a diode having an anode coupled to the first node and a cathode coupled to a body terminal of the first transistor.

2. The accessory device of claim 1, wherein the first transistor comprises a p-channel MOSFET (PMOS) device.

3. The accessory device of claim 1, wherein the second transistor comprises a n-channel MOSFET (NMOS) device.

4. The accessory device of claim 1, further comprising:
a second RC circuit at the first node, wherein the second RC circuit is configured to provide a delay between the voltage rise at the first node and a change in state of the control signal according to a time constant of the second RC circuit.

5. The accessory device of claim 4, wherein the delay between the voltage rise at the first node and a change in state of the control signal is less than 1 ms.

6. The accessory device of claim 1, wherein the first RC circuit is disposed between a source of the first transistor and a drain of the second transistor.

7. The accessory device of claim 1, further comprising:
a microphone; and
a switch coupled between the microphone and the first node, wherein the switch is configured to turn on or off in response to the control signal.

8. The accessory device of claim 1, wherein the accessory device comprises an audio headset with a microphone.

9. The accessory device of claim 1, wherein the accessory device is interfaced with the master device by a 3.5 mm audio jack connection.

10. The accessory device of claim 1, wherein during a transition from the analog mode to the digital mode, the diode is configured to charge a capacitor as a voltage at the first node rises.

11. The accessory device of claim 10, further comprising a resistor (R1) coupled with the first node interfacing the master device and the accessory device, wherein R1<V_{DON}/I_{L}, further wherein V_{DON} is a voltage difference at which the diode turns on, and wherein I_{L} is current through the resistor.

12. The accessory device of claim 11, further comprising a second resistor (R2) in series with the diode, wherein (V_{DIG}-V_{DON})/R2 is less than 50 mA, wherein V_{DIG} is an operating voltage of the digital mode.

13. A method performed by an audio accessory device, the method comprising:
operating the audio accessory device in a first mode, wherein the audio accessory device comprises a first node interfacing the audio accessory device to a master device, the audio accessory device further comprising a first transistor coupled between the first node and a processor chip of the audio accessory device and coupled between the first node and a capacitor, wherein a diode is coupled between the first node and the capacitor and is coupled with a body terminal of the first transistor, wherein during the first mode current is supplied from the master device to the processor chip through a first resistor coupled between the first node and the processor chip;
changing from the first mode to a second mode, including charging the capacitor through the diode and pulling down a gate of the first transistor in accordance with a time constant of a first resistive capacitive (RC) circuit coupled to the gate of the first transistor; and
operating the audio accessory device in the second mode, including supplying current from the master device to the processor chip through the first transistor.

14. The method of claim 13, wherein the first mode includes an analog mode of operation that powers an analog microphone in the audio accessory device and includes transmission of analog signals from the analog microphone to the master device.

15. The method of claim 13, wherein the second mode includes a digital mode of operation, wherein the audio accessory device and master device exchange digital data.

16. The method of claim 13, wherein changing from the first mode to the second mode comprises:
outputting a first value of a control signal by a comparator in response to the comparator receiving a voltage at a first value from the master device;
turning on a second transistor in response to the first value of the control signal; and
turning on the first transistor by pulling down the gate of the first transistor by the second transistor, wherein the first RC circuit is coupled to the first transistor and the second transistor.

17. The method of claim 16, where the comparator senses the voltage at the first value from the master device through a second RC circuit and according to a time delay of the second RC circuit.

18. The method of claim 16, wherein the voltage at the first value is higher than a voltage associated with the first mode.

19. The method of claim 13, wherein the first mode is associated with a first operating voltage, and wherein the second mode is associated with a second operating voltage, further wherein the second operating voltage is higher than the first operating voltage.

20. An audio accessory device comprising:
a first node interfacing with a master device, the first node configured to receive power from the master device and to transmit digital signals between the master device and audio accessory device;
means for conducting current from the first node to a processor chip of the audio accessory device, wherein the means for conducting current includes a first transistor and a diode having its cathode coupled with a body terminal of the first transistor, wherein the diode is configured to conduct current from the first node to the processor chip; and
means for turning on the first transistor according to a first RC time constant.

21. The audio accessory device of claim 20, further comprising:
a second transistor coupled between ground and a gate of the first transistor, a gate of the second transistor configured to receive a control signal.

22. The audio accessory device of claim 21, further comprising:
means for outputting a value for the control signal in response to detecting an operating voltage of the master device at the first node.

23. The audio accessory device of claim 22, further comprising:
means for providing a time delay at an input of the means for outputting a value, according to a second RC time constant.

24. The audio accessory device of claim 20, wherein the first transistor comprises a p-channel MOSFET (PMOS) device.
